(19) United States
(12) Patent Application Publication
(10) Pub. No.: US 2025/0098072 A1
(43) Pub. Date: Mar. 20, 2025

(54) TERMINAL-SENSOR HOLDER

(71) Applicant: TE Connectivity Italia Distribution S.r.l., Torino (IT)

(72) Inventor: Fabio DE PASQUALE, Torino (IT)

(21) Appl. No.: 18/889,833

(22) Filed: Sep. 19, 2024

(30) Foreign Application Priority Data
Sep. 20, 2023 (IT) 102023000019365

(51) Int. Cl. H05K 1/18

(52) U.S. Cl. CPC H05K 1/184; H05K 2201/10045; H05K 2201/1009; H05K 2201/10151

(57) ABSTRACT

A terminal-sensor holder for coupling a stator to a PCB includes a housing having a protruding portion suitable to host a magnetic sensor and at least four terminal seats, wherein each terminal seat is configured to host a magnetic terminal for connecting magnetic wires to the PCB.

### CROSS REFERENCE TO RELATED APPLICATIONS

This application claims the benefit of IT application No. 102023000019365, filed 20 Sep. 2023, the subject matter of which is herein incorporated by reference in its entirety.

### BACKGROUND OF THE INVENTION

The present disclosure relates to the field of terminal-sensor holders. More specifically, the present disclosure relates to the field of insulating holders capable of hosting magnetic sensors and magnetic terminals and suitable to allow the connection between a stator, for example the stator of an electric motor, and a PCB.

In modern technologies, it is often necessary, to be able to connect magnetic coils. For example, it is desired to connect the stator of an electric motor and of a magnetic sensor, with a PCB. These connections are often implemented by soldering processes. The soldering processes present, however, more than one drawback. For example, soldering can be challenging under high-vibration-conditions. Moreover, the soldering process may be difficult due to the need of pre-stripping the magnet wires, which can cause damage of the same. Additionally, problems like fume production and burn hazards are always present, during soldering processes. These problems are amplified if the magnetic wires to be connected are thin, i.e. they have a thickness of less than 0.13 mm. Finally, the costs of the soldering processes are high, and the whole production time is often extended.

In view of the above, it would be advantageous to find a solution that would enable the solderless connection of a stator, a sensor and a PCB.

### BRIEF DESCRIPTION OF THE INVENTION

In one embodiment, a terminal-sensor holder is provided for coupling a stator to a PCB including a housing comprising a protruding portion suitable to host a magnetic sensor and at least four terminal seats, wherein each terminal seat is configured to host a magnetic terminal for connecting magnetic wires to the PCB.

In the ambit of the present disclosure, magnetic wires are conductive wires covered by a covering insulating material. An example of a suitable conductive material is copper. Examples of suitable covering insulating materials are polymer film materials, such as polyvinyl formal (Formvar), polyurethane, polyamide, polyester, polyester-polyimide, polyamide-polyimide (or amideimide), and polyimide. Magnetic wires are typically employed for applications that require tight coils of insulated wire.

The magnetic terminals according to the subject matter herein can be any kind of magnetic terminals known to the skilled person. For example, magnetic terminals that can be used according to the subject matter herein are described in the following prior art documents D1: “Contact Systems for the Automotive Market” by Tyco Electronics, revised 9-2008, downloadable at the link: https://www.the.com/content/dam/the-com/documents/automotive/global/889780-2-contact-systems.pdf (see, for example, section 26, pages 26-1 to 26-18); and D2: U.S. Pat. No. 4,026,013. The teaching of each of these documents is herewith incorporated by reference in its entirety. In particular, the structural and functional properties as well as the methods of employment of the magnetic terminals described in each of these documents are herewith incorporated by reference.

Magnetic terminals described in these documents are also referred to as MAG-MATE terminals.

The teaching of D1 with respect to MAG-MATE terminals is herewith incorporated by reference in its entirety. In particular, all the structural and functional properties of the MAG-MATE terminals described on pages 26-1 to 26-18 of D1 are herewith incorporated by reference. All the possible dimensions and functionalities of the MAG-MATE terminals described on pages 26-1 to 26-18 of D1 are herewith incorporated by reference. The method of operating the system as described on page 26-3 can also be adopted according to embodiments of the subject matter herein and is herewith incorporated by reference in its entirety. The termination sequence as described on page 26-16 can also be adopted according to embodiments of the subject matter herein and is herewith incorporated by reference in its entirety.

As can be seen in D1, there are “Standard MAG-MATE terminals” (see pages 26-1 to 26-14) and “Mini MAG-MATE terminals” (see pages 26-15 to 26-18). Mini MAG-MATE terminals are like those described also in document D2.

According to the subject matter herein, both Standard MAG-MATE terminals and Mini MAG-MATE terminals as described in D1 and D2 can be used. For example, according to an embodiment, all four terminal seats of the housing are configured to house Standard MAG-MATE terminals as those described in D1. According to another embodiment, all four terminal seats of the housing are configured to house Mini MAG-MATE terminals as described in D1 and D2. Still according to another embodiment, two terminal seats of the housing are configured to house Standard MAG-MATE terminals as those described in D1, and the other two are configured to house Mini MAG-MATE terminals as described in D1 and D2,.

By using a terminal-sensor holder according to the subject matter herein, no soldering process and no magnet wire pre-stripping is needed. Therefore, the time and the costs of the assembly process is significantly reduced. The problems related to fumes production and burn hazard are totally overcome. Moreover, the production process can be completely automatized. Finally, the electrical connections between the magnetic wire and PCB are extremely simplified due to the use of the magnetic terminals.

For example, the two end portions of the stator are coupled to two magnetic terminals housed in two terminal seats of the housing and the two end portions of the sensor are coupled to the other two magnetic terminals housed in the other two terminal seats of the housing. The easy and solderless connection of the four magnetic terminals with the PCB allows coupling the stator to the PCB and, at the same time, terminate the magnet wires coming from the magnetic coil wounded on the stator.

According to the subject matter herein, the housing can be made of any suitable insulating material. For example, the housing can be made of nylon, for example a nylon with improved insulation resistance. Alternatively it could be nylon with different glass fiber percentages.

According to an embodiment, each terminal seat further comprises a slit to receive and/or hold the magnetic wires. The magnetic wires are, in this way, mechanically connected to the magnetic terminals and effectively held in place. No soldering process is needed. The slits can advantageously be used to hold the magnetic wires in place before and during insertion of the magnetic terminals in the corresponding terminal seats and thus to guarantee that the magnetic terminals are appropriately coupled to the magnetic wires as described for example in documents D1 and D2.

According to an embodiment, each terminal seat further comprises a supporting element for holding the magnetic wires. These supporting elements allow the magnetic wire to be held at a pre-determined tension. For example, the supporting elements protrude from the housing so as to allow the magnetic wires to be wound around the supporting elements. Preferably, each supporting element is positioned in correspondence to each slit, for example at one extremity of the slit. The supporting elements can advantageously be used to hold the magnetic wires in place before and during insertion of the magnetic terminals in the corresponding terminal seats and thus to guarantee that the magnetic terminals are appropriately coupled to the magnetic wires as described for example in documents D1 and D2.

According to an embodiment, the protruding portion comprises a main body comprising a groove suitable to accommodate the magnetic sensor. The terminal-sensor holder allows, therefore, an easy solution to add a magnetic sensor, connectable to a PCB, to the assembly. No extra pieces and/or space are, in fact, needed since the sensor can be mounted directly on the terminal-sensor holder. For example, the magnetic sensor may comprise a coil formed by a magnetic wire and the coil is advantageously wound around the groove of the protruding portion. The two end portion of the magnetic wire forming the coil can be coupled in a solderless manner to two magnetic terminals housed in two terminal seats of the housing.

According to an embodiment, the four terminal seats form two pairs of equal terminal seats, so as to host two different types of magnetic terminals. The magnetic terminals of the first type can be used for example for coupling with the end portions of the magnetic wires of the sensor whereas the magnetic terminals of the second type can be used for coupling with the end portions of the magnetic wires of the stator. In this way, the magnetic wires of the stator and of the sensor could be different magnetic wires, for example magnetic wires with different diameters. The two pairs of terminal seats can, for example, be realized so as to host two Standard MAG-MATE terminals as described in D1 and two Mini MAG-MATE terminals, as those described in D1 or D2. The subject matter herein, however, is not limited to this embodiment and the terminal seats can be adapted to host any kind of needed magnetic terminal.

According to an embodiment, the first type of magnetic terminals are suitable to connect magnetic wires with a lower diameter than the magnetic wires connected to the second type of magnetic terminals. The first magnetic terminals can, in fact be, for example, suitable to connect thin magnetic wires, with a thickness comprised, for example, between 0.05 mm and 0.13 mm. For example, the first magnetic terminals can be Mini MAG-MATE terminals as those described in documents D1 pages 26-15 to 26-18 or D2. The second magnetic terminals can be, for example, suitable to connect thicker magnetic wires with a thickness comprised, for example, between 0.18 mm and 0.23 mm. For example, the second magnetic terminals can be Standard MAG-MATE terminals as those described in D1 on pages 26-1 to 26-14. This increases the versatility in the possible choice of magnetic wiring for the sensor and the stator.

According to an embodiment, the housing further comprises a PCB holder portion for housing the PCB. The PCB holder portion may comprise a pair of parallel rails to hold the PCB. The PCB holder portion may be configured to allow the connection between the PCB and the magnetic terminals housed in the terminal seats of the housing. This facilitates the procedure by which a PCB is mounted onto the terminal-sensor holder. For example, the PCB holder portion is located directly above the terminal seats. Preferably, the PCB holder portion is located on the side of the housing opposed to the side from which the protruding portion protrudes.

According to another embodiment, a terminal-sensor holder assembly is provided comprising a terminal-sensor holder according to any of the embodiments of the subject matter herein described above and at least four magnetic terminals to be inserted into the four terminal seats. The four magnetic terminals allow a mechanical easy connection of the magnetic wires of both a stator and of a sensor to a PCB. Soldering is no longer needed. The four magnetic terminals could be any of the magnetic terminals described in documents D1 and D2.

According to an embodiment, the four magnetic terminals form two pairs of equal terminals, so as to connect two different types of magnetic wires. The two types of magnetic wires can be magnetic wires with different thicknesses. Thin magnetic wires, like the ones of the magnetic sensor, can have a thickness comprised, for example, between 0.05 mm and 0.13 mm. Thicker magnetic wire, like the ones of the stator coil, can have a thickness comprised, for example, between 0.18 mm and 0.23 mm. The magnetic terminals for thin magnetic wires can, for example, be Mini MAG-MATE terminals as described in D1 pages 26-15 to 16-18 or D2. The magnetic terminals for thicker wires can, for example, be standard MAG-MATE terminals as described in D1, pages 26-1 to 26-14,.

According to an embodiment, the magnetic terminals are MAGMATE terminals. A description of these known magnetic terminals can be found in documents D1 and D2,. The structural and functional properties as well as the methods of employment of the magnetic terminals described in each of these documents are herewith incorporated by reference.

According to an embodiment, the terminal-sensor holder assembly further comprises a magnetic sensor placed on the protruding portion. No extra pieces or space is needed in order to add a magnetic sensor. The magnetic sensor can comprise a coil formed by a magnetic wire. The two end portions of the magnetic wire forming the coil can be coupled to two magnetic terminals to be housed in two of the terminal seats of the housing.

According to an embodiment, the magnetic sensor comprises a coil that is wound around the groove. The design of the terminal-sensor holder allows an easy solution to add a magnetic sensor, connectable to a PCB, to the assembly.

According to an embodiment, the terminal-sensor holder assembly further comprises a PCB. The connection to the PCB is realized by inserting the PCB pins inside the magnetic terminals. This procedure is easy and soldering is completely avoided. The PCB can be structured and dimensioned to be housed by the housing of the terminal-sensor holder. For example, the PCB can be structured and dimensioned to be housed by the PCB holder portion of the housing.

According to another embodiment, a sensor system is provided comprising a terminal-sensor holder according to any of the embodiments of the subject matter herein described above, a magnetic sensor placed on the protruding portion and a stator, wherein the protruding portion is inserted inside the stator, so that the magnetic sensor can detect the current flowing in the stator. The design of the terminal-sensor holder is compact, easy to mount and avoids soldering processes.

According to an embodiment, the magnetic sensor comprises a sensor coil and the stator comprises a stator coil, wherein the ends of said sensor coil and the ends of said stator coil are each connected to one of the four magnetic terminals. The magnetic terminals allow the connection of magnetic wire with different thickness, without resort to soldering processes.

According to an embodiment, the sensor system further comprises a PCB connected to at least two, preferably four, of the magnetic terminals. The connection to the PCB is easy and simply requires the mechanical insertion of the PCB pins inside the magnetic terminals.

According to further embodiments, a method for assembling a sensor system is provided comprising: providing a terminal-sensor holder according to any of the embodiments described above; providing a sensor on the protruding portion, whereby the ends of the sensor are inserted in two of the four terminal seats; inserting the protruding portion inside a stator; inserting the ends of the stator in the other two of the four terminal seats and inserting magnetic terminals in the terminal seats.

According to an embodiment, the method further comprises: providing a PCB and connecting the PCB to at least two, preferably four, of the magnetic terminals.

The method according to the subject matter herein, by using the terminal-sensor holder according to the subject matter herein, allows an easy, fast and cheap solution to connect a stator, for example, of an electric motor and a magnetic sensor to a PCB without soldering.

### BRIEF DESCRIPTION OF THE DRAWINGS

The present invention will be described with reference to the attached figures, in which the same reference numerals and/or signs indicate the same part and/or similar and/or corresponding parts of the machine.

FIG. 1 schematically shows a 3D view of a terminal-sensor holder according to an exemplary embodiment.

FIG. 2A shows the terminal-sensor holder, shown in FIG. 1 rotated 90° clockwise on the XY plane from above, with a pair of magnetic terminals ready to be inserted in it.

FIG. 2B shows the terminal-sensor holder shown in FIG. 2A with a pair of magnetic terminals inserted in it, and a further pair of magnetic terminals ready to be inserted.

FIG. 2C shows the terminal-sensor holder shown in FIG. 2A with all four magnetic terminals inserted in it.

FIG. 3A schematically shows a 3D view of a type of terminal seat according to an embodiment, rotated 90° clockwise on the XY plane with respect to FIG. 2C, with a wire inserted in it.

FIG. 3B shows a cross section of the terminal seat shown in FIG. 3A, along the AA direction, at the moment in which a magnetic terminal is inserted in it.

FIG. 4 schematically shows a 3D view of a stator coil wound around an insulating stator coil holder and with a stator coil cover in position to be mounted on it.

FIG. 5A schematically shows a 3D view of the outer portion of a metallic stator case.

FIG. 5B schematically shows a 3D view of the inner portion of a metallic stator case.

FIG. 6 schematically shows an upside-down view, with respect to FIG. 1, of a terminal-sensor holder with a sensor coil wound around the groove of its protruding portion according to an embodiment.

FIG. 7 schematically shows the terminal-sensor holder, as shown in FIG. 6, mounted inside the metallic stator case shown in FIGS. 5A and 5B.

FIG. 8 shows the terminal-sensor holder as shown in FIG. 7, with a PCB mounted on it.

FIG. 9 illustrates a magnetic terminal.

FIG. 10 illustrates a magnetic terminal.

### DETAILED DESCRIPTION OF THE INVENTION

In the following, the present invention is described with reference to particular embodiments, as shown in the enclosed drawings. Nevertheless, the present invention is not limited to the particular embodiments described in the following detailed description and shown in the figures, instead, the embodiments described simply exemplify several aspects of the present invention, the scope of which is defined by the appended claims.

Further modifications and variations of the present invention will be clear for the person skilled in the art. Therefore, the present description has to be considered as including all the modifications and/or variations of the present invention, the scope of which is defined by the appended claims.

For simplicity, identical or corresponding components are indicated in the figures with the same reference numbers.

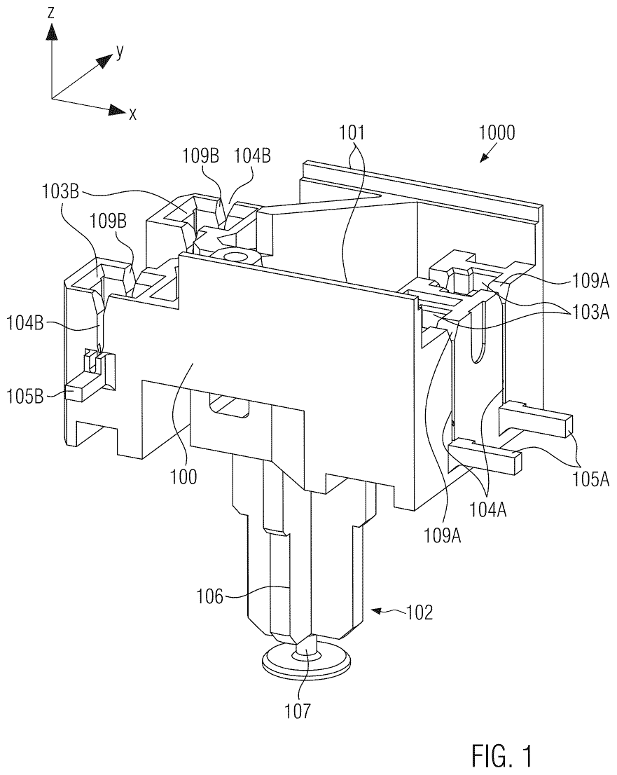

FIG. 1 shows a 3D view of a terminal-sensor holder 1000 according to an embodiment.

To facilitate the description, with reference to FIG. 1, an orthogonal reference system XYZ is defined. More in particular, the vertical direction Z is defined as the direction along which the magnetic terminals 300A and 300B can be inserted inside the terminal-sensor holder 100, the horizontal direction Y is defined as the direction in which the supporting elements 105A, suitable to hold the sensor magnetic wires 202, stick out from the terminal-sensor holder 1000 and the direction X is defined as the direction perpendicular to the previous two directions.

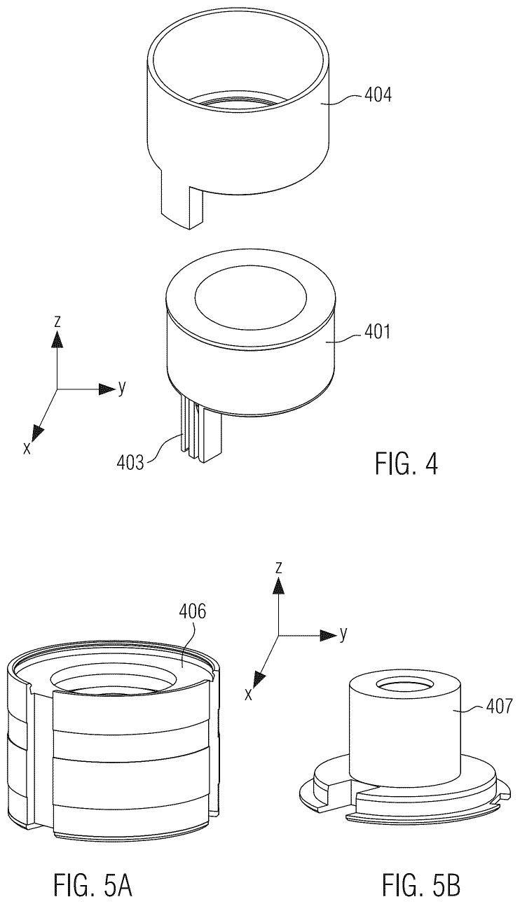

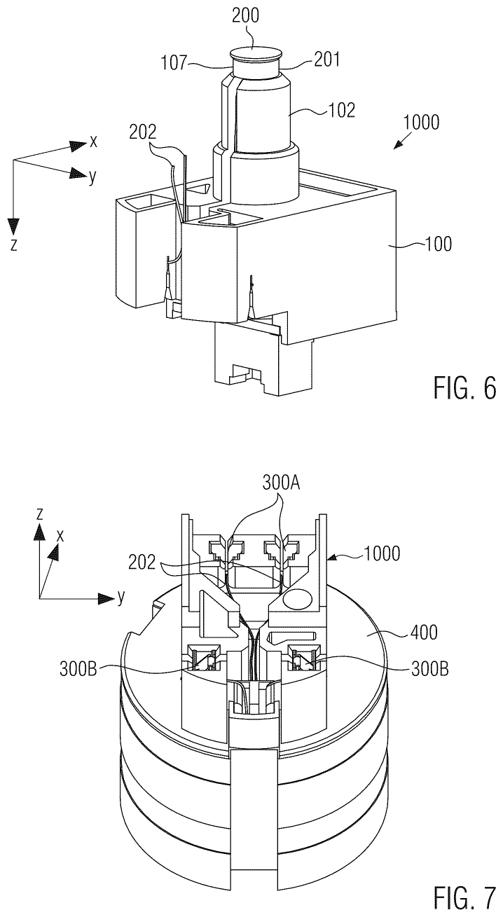

The terminal sensor holder 1000 comprises a housing 100 made of an insulating material, for example, hard plastic. The housing 100 comprises at least four terminal seats, i.e. two terminal seats 103A and two terminal seats 103B. The at least four terminal seats 103A, 103B are equal in pairs. Two of them are, in fact, suitable to host a first type of magnetic terminal 300A and the other two are suitable to host a second type of magnetic terminal 300B. More in particular, according to a preferred embodiment of the invention, a first pair of terminal seats 103A are suitable to host a first type of magnetic terminals 300A and the terminal ends of the sensor magnetic wires 202 of a sensor coil 201 of a magnetic sensor 200, better described with reference to FIG. 6. The other two terminal seats 103B are suitable to host a second type of magnetic terminals 300B and the terminal ends of the stator magnetic wires 202 of a stator coil 201 of a stator 200, better described with reference to FIGS. 4, 5A and 5B. Examples of these magnetic terminals 300A and 300B are described in documents D1 and D2. A description of the magnetic sensor 200 with sensor magnetic wires 202 and of the stator 400 with stator magnetic wires 402, can be found in the description of FIGS. 4, 5A, 5B and 6.

Each terminal seat 103A, 103B comprises a V opening 109A, 109B, through which a magnetic wire 202, 402 can be guided into the slit 104A, 104B of the terminal seat 103A, 103B, a slit 104A, 104B and a supporting element 105A, 105B suitable to hold in place the magnetic wire 202, 402 inserted inside the slit 104A, 104B. More in particular, the first supporting elements 105A of the first type of terminal seats 103A stick out the housing 100 along the X direction and the second supporting elements 105B of the second type of terminal seats 103B stick out of the housing 100 along the Y direction in opposite directions, with respect to each other.

The main body 100 further comprises a protruding portion 102, comprising at its terminal end a groove 107. The protruding portion is suitable to be inserted inside a stator 400, as better described with reference to FIG. 7. The groove 107 is suitable to host a magnetic sensor 200, as better shown and described with reference to FIG. 6. The housing 100 further comprises a PCB holder 101. The PCB holder 101 comprises a rail structure that facilitate the insertion of a PCB 500 onto the housing 100 of the terminal-sensor holder 1000.

The main body 100 additionally comprises guides 108 to guide the terminal ends of the sensor magnetic wire 202 of the sensor coil 201 of the magnetic sensor 200 from the groove 107 to the first terminal seats 103A.

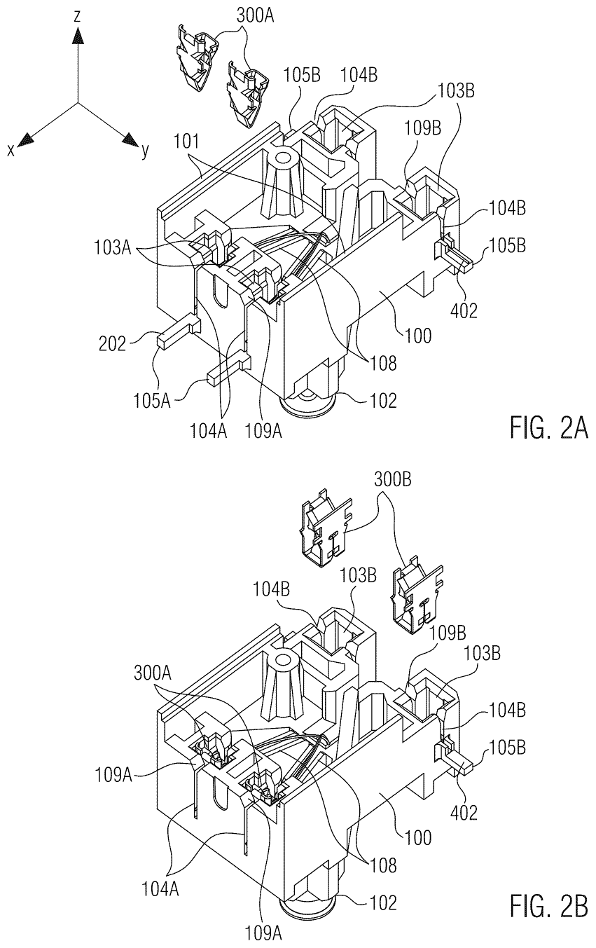

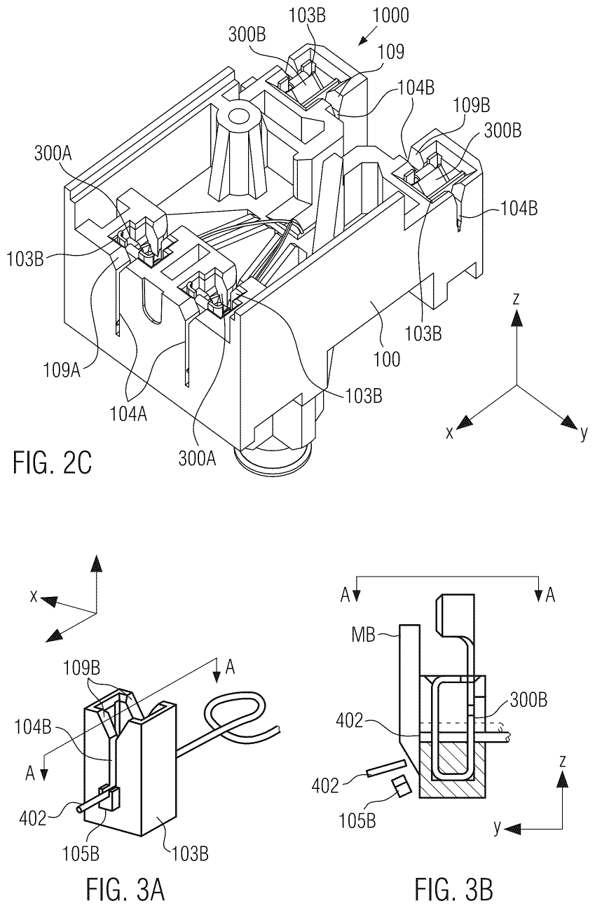

FIG. 2A shows the terminal-sensor holder 1000 shown in FIG. 1, rotated 90° clockwise on the XY plane, from above, with a pair of magnetic terminals 300A, ready to be inserted in it.

The magnetic terminals 300A can be magnetic terminals of the type described in documents D1, on pages 26-15 to 26-18 and D2. The magnetic terminals 300A can be inserted inside the corresponding terminal seats 103A along the Z direction. These magnetic terminals 300A can be for example Mini MAG-MATE terminals.

The terminal-sensor holder 1000, as shown in FIG. 2A, and as better shown in FIG. 6, already has a magnetic sensor 200 mounted on the groove 107 of the protruding portion 102 of the housing 100. The magnetic sensor 200 comprises a sensor coil 201 comprising a sensor magnetic wire 202 wound around the groove 107. The sensor magnetic wires 202 may have a diameter comprised between 0.05 mm and 0.13 mm. The two free ends of the sensor magnetic wire 202 are inserted inside the housing 100 and through the guides 108 they go inside the terminal seats 103A and through the slits 104A, to be wound around the supporting element 105A. The fact that the sensor magnetic wires 202 are wound around the supporting elements 105A allows the sensor magnetic wires 202 to stay properly tense, for example before or during insertion of the magnetic terminals 300A. Winding magnetic wires which such low thickness around the supporting element 105A allows easily and safely keeping the wire at the desired tension and position. Without the supporting element 105A, it would be difficult to keep the wire at the desired tension and position by simply holding it inside the slit 104A.

FIG. 2B shows the terminal-sensor holder shown in FIG. 2A, with the pair of magnetic terminals 300A already inserted in it and a further pair of magnetic terminals 300B ready to be inserted in it.

The magnetic terminals already inserted are the first type of magnetic terminals 300A, as described for example in documents D1, pages 26-15 to 26-18, or D2. The pair of magnetic terminals 300B, ready to be inserted, can be magnetic terminals of the type described for example in document D1, pages 26-1 to 26-14. The magnetic terminals 300B can be inserted inside the corresponding terminal seats 103B along the Z direction. These magnetic terminals 300B can be for example Standard MAG-MATE terminals.

Advantageously, when the first magnetic terminals 300A are inserted inside the first type terminal seats 103A, the supporting elements 105A and the end portions of the sensor magnetic coil 202 are cut, as can be seen comparing FIG. 2B with FIG. 2A. For example, a machine used to place the first magnetic terminals 300A inside the first type terminal seats 103A, while inserting the magnetic terminals 300A also cuts the supporting elements 105A and the portion of the sensor magnetic coil 202 sticking out of the terminal-sensor holder 1000, using a blade MB. In fact, the sensor magnetic wires 202, are now held in place by and electrically connected to the first type of magnetic terminals 300A. Insertion and termination of the magnetic terminals 300A can be carried out as described in D1, on pages 26-15 to 26-18, in particular on page 26-16, or D2. The teaching of each of these documents in this respect is herewith incorporated by reference.

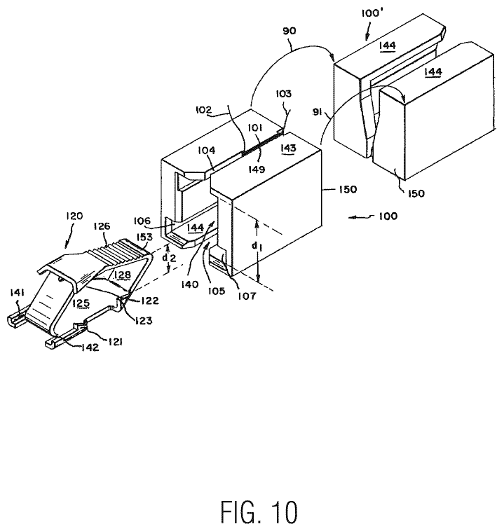

For example, with reference to D2 and, in particular, to FIG. 1 of the document, reproduced herein as FIG. 10, the first type magnetic terminals indicated with number 120 in FIG. 2 of D2, in fact, comprise a grating blade element, indicated with number 126 in D2, that partially grates away the covering insulating material of the sensor magnetic wire 202, while being inserted inside the corresponding terminal seat 103A. In this way, the portion of the conductive wire is no longer covered by the covering insulating material, touches the magnetic terminal 300A, and is, therefore, electrically connected to it.

The terminal-sensor holder 1000, as shown in FIG. 2B already has the stator magnetic wires 402 of a stator coil 401 of a stator 400 mounted inside the housing 100. For this to be really the case, the terminal-sensor holder has to already be inserted inside the stator 400, as shown in FIG. 7, but for simplicity in FIG. 2B only the terminal-sensor holder 1000, with the stator magnetic wires 402 in position inside the housing 100, is shown. The thickness of the stator sensor coil 402 can be comprised between 0.18 mm and 0.23 mm. The stator magnetic wires 402 pass through the second type terminal seats 300B, being inserted inside the slits 104B. The stator magnetic wires 402 lay on the support elements 105B, that hold the stator magnetic wires 402 in place.

FIG. 2C shows the terminal-sensor holder shown in FIG. 2A with all the four magnetic terminals inserted in it.

Advantageously, when the second magnetic terminals 300A are inserted inside the second type terminal seats 103B, the supporting elements 105B and the end portions of the stator magnetic coil 402 are cut, as can be seen comparing FIG. 2C with FIG. 2B. For example, the machine used to place the second magnetic terminals 300B inside the second type terminal seats 103B, while inserting the magnetic terminals 300B, also cuts the supporting elements 105B and the portion of the stator magnetic coil 402 sticking out of the terminal-sensor holder 1000, using a blade MB, as shown in FIG. 3B.

The stator magnetic wires 402 are now held in place by and electrically connected to the second type of magnetic terminals 300B.

Insertion and termination of the magnetic terminals 300B can be carried out as described in D1 on pages 26-1 to 26-14, in particular on page 26-3. The teaching this document in this respect is herewith incorporated by reference.

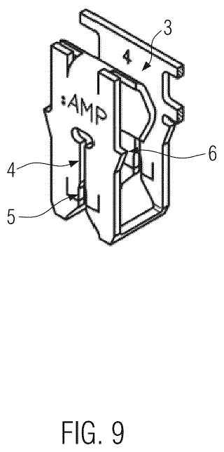

For example, with reference to D1 and, in particular, to FIG. 3, page 26-3 of the document, reproduced herein as FIG. 9, the second type of magnetic terminals, comprise parallel fissures, indicated with numbers 4 in FIG. 3, page 26-3 of D1, in which the magnetic wire is inserted and cutting blades element, indicated with number 4 in the same figure, that laterally cuts the covering insulating material of the stator magnet wire 402, without damaging the conductive wire covered by it. In this way, the portion of the conductive wire no longer covered by the covering insulating material touches the magnetic terminal 300B and is therefore, electrically connected to it.

FIG. 3A shows a 3D view of the second type of terminal seat 103B, according to an embodiment, rotated 90° clockwise on the XY plane with respect to FIG. 2C, with a wire inserted in it. The figure shows the terminal seat 103B in which a stator magnetic wire 402 has been inserted, the stator magnetic wire 402 being held in place by the supporting element 105B. Supporting element 105B comprises a slit suitable to hold the magnetic wire 402.

FIG. 3B shows a cross section of the terminal seat shown in FIG. 3A, along the AA direction, at the moment in which a machine is inserting a magnetic terminal 300B in it. The figure shows the blade MB of the machine used to insert the magnetic terminal 300B cutting the stator magnetic coil 402 sticking out of the terminal seat 103B and the support element 105B.

FIG. 4 shows a 3D view of a stator coil 401 wound around an insulating stator coil holder 403 and with a stator coil cover 404 in position to be mounted on it.

The stator magnetic wire 402 is wound around a stator coil holder 403 to form a stator coil 401. The number of windings can be, for example, 750. Then the stator coil holder 403 and the stator coil 401 are inserted inside a stator coil cover 404, serving as a first protective element for the stator coil 401. Both the stator coil holder 403 and the stator coil cover 404 have a cylindrical form and are made of an insulating material, for example a hard plastic.

FIG. 5A shows a 3D view of the outer portion of a metallic stator case 405.

FIG. 5B shows a 3D view of the inner portion of a metallic stator case 405.

The stator case 405 comprises an inner portion 407 made of a metallic material and an outer portion 406 made of a metallic material. The inner portion 407 is in the form of a cylinder suitable to be inserted inside the stator coil holder 403. The outer portion 406 is in the form of a cylinder suitable to surround the stator coil holder 403. The inner portion 407 and the outer portion 406 are made so as to be coupled to each other and, when in place, so as to form a stator case 405 that completely surrounds the stator coil cover 404 containing the stator coil 401.

FIG. 6 shows an up-side-down view of a terminal-sensor holder 1000 with a sensor coil 201 wound around the groove 107 of its protruding portion 102.

A sensor magnetic wire 202 with a thickness comprised between 0.05 mm and 0.23 mm is wound around the groove 107 of the protruding portion 102 of the sensor-terminal holder 1000. The number of windings can be, for example, 183. The ends of the sensors magnetic wire are inserted into the slits 104A of the terminal seats 103A, as better explained with reference to FIG. 2A. The sensor-terminal holder 1000 now holds the magnetic sensor 200.

FIG. 7 shows the terminal-sensor holder 1000, as shown in FIG. 6, mounted inside a metallic stator case 405.

The sensor-terminal holder 1000 with the magnetic sensor 200 mounted on it is now inserted inside the stator case 405, so that the sensor coil 201 results to be inside the stator case 405 and the terminal seats 103A and 103B face upwards.

In this position, the magnetic sensor 200 can detect the current flowing in the stator 400.

At this point, it is also possible to insert the ends of the stator magnetic wire 402 in the corresponding terminal seats 103B, as shown in FIG. 2A.

Finally, the magnetic terminals 300A and 300B can be inserted into the respective terminal seats 103A, 103B. The same are, automatically also put in electrical contact with the corresponding magnetic wires 202, 402, as explained with reference to FIGS. 2A and 2C,.

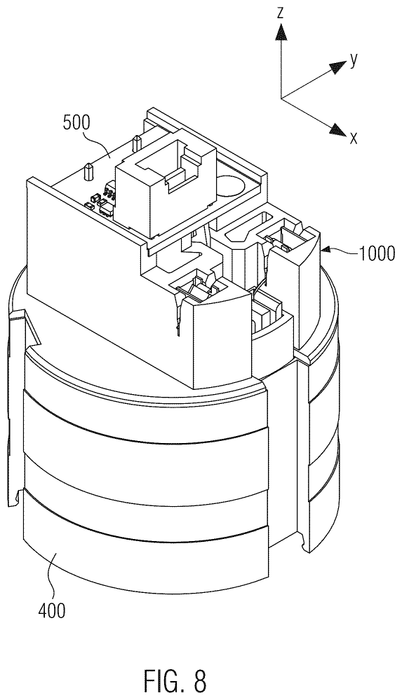

FIG. 8 shows the terminal-sensor holder 1000 as shown in FIG. 7, mounted on the stator 400 and with a PCB mounted on it.

The assembly constituted by the terminal-sensor holder 1000 with the magnetic sensor 200 mounted on it, inserted inside the stator 400 and with the magnetic terminals 300A and 300B in place in the corresponding terminal seats 103A and 103B is now ready to be connected to a PCB 500. This can be achieved very easily because the connecting pins 501 of the PCB 500 can be directly inserted inside the magnetic terminals 300A and 300B. The PCB 500 can be connected to at least two, preferably four, of the magnetic terminals 300A and 300B. The PCB holder 101 of the housing 100 assures the proper positioning of the PCB 500 onto the terminal-sensor holder 1000.

The subject matter herein further concerns a method for assembling a terminal-sensor system. The method comprises the following steps:
providing a terminal-sensor holder, see for example FIG. 1;
providing a sensor on the protruding portion, whereby the ends of the sensor are inserted in two of the four terminal seats, see for example FIG. 6 and FIG. 2A;
inserting the protruding portion inside a stator, see for example FIG. 7;
inserting the ends of the stator in the other two of the four terminal seats, see for example FIG. 2B;
inserting magnetic terminals in the terminal seats, see for example FIG. 2A to 2C;
providing a PCB and connecting the PCB to at least two, preferably four, of the magnetic terminals, see for example FIG. 8.

The method, by using the terminal-sensor holder 1000, allows an easy, fast and cheap solution to connect a stator 400 and a sensor 200 to a PCB 500. No soldering is needed.

Even though the present invention has been described with reference to the embodiments described above, it is clear to those skilled in the art that it is possible to make different modifications of the present invention in light of the teaching described above and in the appended claims, without departing from the scope of protection of the invention.

For example, the thickness and number of the magnetic wires to connect can vary, depending on the kind and the number of elements to be connected to the PCB. For example, the standard MAGMATE can terminate up to 2 wires each, so the number of coils could be increased up to 6.

Accordingly, the number and type of terminal seats in the housing can vary according to the magnetic wires to be connected and therefore, according to the magnetic terminals they need to host. The kind of magnetic terminals needed is, in fact, a function of the magnetic wires thickness and can vary according to needs.

Finally, those aspects that are considered known by those skilled in the art have not been described in order to avoid excessively obscuring the description of the invention.

Consequently, the invention is not limited to the embodiments described above, but is only limited by the scope of protection of the appended claims.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. § 112 (f), unless and until such claim limitations expressly use the phrase “means for” followed by a statement of function void of further structure.

What is claimed is:

1. Terminal-sensor holder for coupling a stator to a PCB, the terminal-sensor holder comprising:
a housing including a protruding portion configured to host a magnetic sensor and at least four terminal seats,
wherein each terminal seat is configured to host a magnetic terminal for connecting magnetic wires to said PCB.

2. Terminal-sensor holder according to claim 1, wherein each terminal seat further comprises a slit to receive and/or hold the magnetic wires.

3. Terminal-sensor holder according to claim 1, wherein each terminal seat further comprises a supporting element for holding the magnetic wires.

4. Terminal-sensor holder according to claim 1, wherein the protruding portion comprises a main body comprising a groove suitable to accommodate the magnetic sensor.

5. Terminal-sensor holder according to claim 1, wherein said four terminal seats form two pairs of equal terminal seats, so as to host two different types of magnetic terminals.

6. Terminal-sensor holder according to claim 5, wherein the first type of magnetic terminals is suitable to connect magnetic wires with a lower diameter than the magnetic wires connected to the second type of magnetic terminals.

7. Terminal-sensor holder according to claim 1, wherein said housing further comprises a PCB holder portion for housing said PCB.

8. Terminal-sensor holder assembly comprising:
a terminal-sensor holder for coupling a stator to a PCB, the terminal-sensor holder including a housing including a protruding portion configured to host a magnetic sensor and at least four terminal seats; and
at least four magnetic terminals inserted into said four terminal seats, the magnetic terminals for connecting magnetic wires to said PCB.

9. Terminal-sensor holder assembly according to claim 8, wherein:
said four terminal seats form two pairs of equal terminal seats, so as to host two different types of magnetic terminals; and
said four magnetic terminals form two pairs of equal terminals, so as to connect two different types of magnetic wires.

10. Terminal-sensor holder assembly according to claim 9, wherein the first type of magnetic terminals is suitable to connect magnetic wires with a lower diameter than the magnetic wires connected to the second type of magnetic terminals.

11. Terminal-sensor holder assembly according to claim 8, wherein said magnetic terminals are MAG-MATE terminals.

12. Terminal-sensor holder assembly according to claim 8, further comprising a magnetic sensor placed on said protruding portion.

13. Terminal-sensor holder assembly according to claim 12, wherein:
said protruding portion comprises a main body comprising a groove suitable to accommodate the magnetic sensor; and
said magnetic sensor comprises a coil and said coil is wound around said groove.

14. Terminal-sensor holder assembly according to claim 8, further comprising a PCB.

15. Sensor system comprising:
a terminal-sensor holder including a housing including a protruding portion and at least four terminal seats, wherein each terminal seat is configured to host a magnetic terminal for connecting magnetic wires to a PCB;
a magnetic sensor placed on said protruding portion; and
a stator;
wherein said protruding portion is inserted inside said stator so that said magnetic sensor can detect the current flowing in said stator.

16. Sensor system according to claim 15, wherein said magnetic sensor comprises a sensor coil and said stator comprises a stator coil, wherein the ends of said sensor coil and the ends of said stator coil are each connected to one of said four magnetic terminals.

17. Sensor system according to claim 15, further comprising a PCB connected to at least two of said magnetic terminals.

18. Method for assembling a sensor system, comprising:
providing a terminal-sensor holder for coupling a stator to a PCB, the terminal-sensor holder including a housing including a protruding portion and at least four terminal seats, wherein each terminal seat is configured to host a magnetic terminal for connecting magnetic wires to said PCB;
providing a sensor on said protruding portion, whereby ends of said sensor are inserted into two of said four terminal seats;
inserting said protruding portion inside a stator;
inserting ends of said stator in the other two of said four terminal seats; and
inserting magnetic terminals in said terminal seats.

19. Method according to claim 17, further comprising:
providing a PCB and connecting said PCB to at least two of said magnetic terminals.
